(19) United States
(12) Patent Application Publication
(10) Pub. No.: US 2009/0266454 A1
(43) Pub. Date: Oct. 29, 2009

(54) Method of Diffusion Zinc Coating

(75) Inventors: Wolfram Graf, Essen (DE); Frank Natrup, Sprockhoevel (DE); Martin Pohl, Altenbeken (DE)

Correspondence Address: HUNTON & WILLIAMS/NEW YORK;INTELLECTUAL PROPERTY DEPT., 1900 K STREET, N.W., SUITE 1200, WASHINGTON, DC, 20006-1109, US

(73) Assignees: Bodycote Warmebehandlung GmbH, Ebersbach (DE); Benteler Automobiltechnik GmbH, Paderborn (DE)

(21) Appl. No.: 12/427,351

(22) Filed: Apr. 21, 2009

(30) Foreign Application Priority Data
Apr. 24, 2008 (DE) 10 2008 020 576.1

(51) Int. Cl. B05D 3/02; C22F 1/00; C23C 14/34; C21D 6/00

(52) U.S. Cl. 148/537; 148/712; 148/579; 148/679; 148/688; 148/558; 204/192.14

(57) ABSTRACT

In a method for the coating of a surface of at least one substrate with zinc in which the at least one substrate to be coated is heat treated together with zinc as the coating agent at a temperature between 200 and 500° C., wherein, before the start of the heat treatment in the reaction space in which the substrate to be coated is heat treated, the oxygen content in the atmosphere contained in the reaction space is set to less than/equal to 5 volume percent and the heat treatment is then started in the atmosphere obtained in this manner in the reaction space and the heat treatment is carried out in the reaction space, with no gas being supplied into the reaction space during the heat treatment or with no gas containing oxygen being supplied or with gas being supplied which has been pretreated so that it has an oxygen content of a maximum of 100 ppm.

### FIELD OF THE INVENTION

The present invention relates to a method for the coating of a surface of at least one substrate with zinc in which the substrate to be coated is heat treated together with zinc as the coating agent at a temperature between 200 and 500° C.

### BACKGROUND OF THE INVENTION

Components of material prone to corrosion such as iron and steel have long been zinc coated, i.e. provided at their surfaces with a comparatively thin zinc layer to increase the corrosion resistance of the components. Examples for such components are connection elements and fastening elements such as screws and bolts, body parts for motor vehicles, crash barriers, banisters, outside steps and the like. Hot-dipping, galvanization and sherardizing are known as zinc coating methods.

In hot-dipping, the substrate to be coated is dipped, after a corresponding pretreatment which normally includes the steps of degreasing, stripping, fluxing and drying, into a zinc melt which usually has a temperature between 440° to 460° C. and is left in this melt for a sufficient time before the substrate coated in this manner is removed from the melt, cooled and optionally posttreated. A disadvantage of hot dipping is found in the attempt to coat plated high-strength steel parts since these can decisively lose strength and can thereby become unusable under the influence of the relatively high process temperature of more than 450° C.

In galvanization, the application of the zinc layer onto the product to be zinc coated takes place by electrochemical deposition from a zinc electrolyte. However, this method is only applicable with restrictions for substrates of complex shape. Furthermore, plated high-strength steel parts may not be treated with this process to preclude the danger of hydrogen embrittlement.

A further known zinc coating process is sherardizing in which the product to be zinc coated is heat treated with zinc powder, usually in a mixture with an inert material or filler such as sand or ceramic material, for example alumina or silicon carbide, at a temperature between 350 and 415° C. As a rule, the process is carried out in a heatable rotating drum in which the product to be zinc coated is embedded into the mixture of zinc powder and filler before the drum is sealed in an airtight manner after the filling and is heated to the required temperature. The filler used in the sherardizing process has a plurality of functions. On the one hand, this provides a uniform heating, a gentle cleaning of the components and a homogeneous distribution of the zinc powder. In addition, this prevents a smashing together and thus damage of the components in the case of bulk material. The sherardizing process is a diffusion coating process in which zinc is diffused from the vapor phase, which is formed by sublimation due to the comparatively high vapor pressure of zinc at the temperature used for the heat treatment, into the surface coating of the substrate to be zinc coated. Processes of this type are described, for example, in the patents DE 134 594, in DE 273 654 and by E. V. Proskurkin & N. S. Gorbunov, “Galvanizing, sherardizing and other zinc diffusion coatings”, Technicopy Limited, England, 1972, pages 1 to 68.

With the sherardizing process, very uniform zinc coatings which adhere strongly to the substrate, have a layer thickness between 10 and 100 μm and have an outstanding corrosion resistance are obtained even on the use of substrates of complex shape. However, the known sherardizing processes have some disadvantages.

One disadvantage of the currently known sherardizing processes is the comparatively high zinc consumption which is caused by the burning of the zinc in the air atmosphere initially present in the reaction space having an oxygen concentration of 21 volume percent. In addition, disadvantages are associated with the use of the filler, and indeed both for complex components which are usually fixed in racks in the drum and also for the process. Unwanted deformation of the product to be zinc coated can namely arise due to the filler's own weight. Furthermore, due to the thermal capacity of the filler, considerably more heating energy is required for the process than if the filler were dispensed with. The filler furthermore requires additional process steps and handling apparatus. The filler has, for instance, to be added into the drum before the sherardizing and must subsequently be separated from the coating product and be cleaned for reuse. If the filler is dispensed with to avoid these disadvantages, it has been shown in practice that the process with a usual zinc dosage no longer results in the layer formation and thus fails or that the zinc consumption is considerably increased with respect to the zinc coated surface. In addition, on a dispensing with the addition of filler in the drum, significant amounts of iron oxides can form which are disadvantageous for the coating process.

It is therefore the object of the present invention to provide a method for the coating of a surface of a substrate with zinc with which very uniform zinc coatings which adhere strongly to the substrate and have outstanding corrosion resistance can be obtained even with substrates of complicated shape are used, said method additionally having a low zinc consumption with respect to the surface of the substrate to be zinc coated and with which the use of a filler can be dispensed with.

### SUMMARY OF THE INVENTION

In accordance with the invention, this object is satisfied by the provision of a method for the coating of a surface of at least one substrate with zinc in which the at least one substrate to be coated is heat treated together with zinc as the coating agent at a temperature between 200 and 500° C., wherein, before the start of the heat treatment in the reaction space in which the substrate to be coated is heat treated, the oxygen content in the atmosphere contained in the reaction space is set to less than or equal to 5 volume percent and the heat treatment is then started in the atmosphere obtained in this manner in the reaction space and the heat treatment is carried out in the reaction space, with no gas being supplied into the reaction space during the heat treatment or with no gas containing oxygen being supplied or with gas being supplied which has been pretreated so that it has an oxygen content of a maximum of 100 ppm.

### DETAILED DESCRIPTION OF THE INVENTION

Within the framework of the present invention, it was surprisingly able to be found that in a method for the coating of a surface of a substrate with zinc, wherein the substrate to be coated is heat treated together with zinc as the coating agent at a temperature between 200 and 500° C., a zinc coating of the surface of the substrate is possible while producing a zinc coating of uniform thickness, preferably between 10 and 100 μm, which results in outstanding corrosion resistance and adheres strongly to the substrate even on the use of a substrate with a complicated shape with a low zinc consumption with respect to the surface of the substrate to be zinc coated, even if the use of a filler is dispensed with, if the heat treatment in the reaction space in which the substrate to be coated is heat treated, the oxygen content in the atmosphere contained in the reaction space is set to less than or equal to 5 volume percent and the heat treatment is only then started in the atmosphere produced in this manner in the reaction space and the heat treatment is carried out in the reaction space, with no gas being supplied into the reaction space during the heat treatment or with no gas containing oxygen being supplied or with gas being supplied which has been pretreated so that it has an oxygen content of a maximum of 100 ppm. Due to the lower zinc consumption, the process costs can be reduced by up to 40% in the method in accordance with the invention in comparison with the process known from the prior art. In accordance with the finding of the present invention, this is due to the fact that the oxygen content in the reaction space amounts to less than 5 volume percent at the start of the heat treatment and the oxygen content is then further reduced in the reaction space by the heat treatment process without further oxygen or maximum trace amounts of oxygen being supplied to the reaction space from the outside after the start of the heat treatment, whereas in the known sherardizing process used in production scale the heat treatment takes place in a heated, rotating reaction space which is sealed after the loading with the product to be zinc coated and the mixture of zinc powder and filler taking place in air atmosphere (that is in an atmosphere containing 21% oxygen) before the reaction space is heated to the required temperature. Since the oxygen content in the method in accordance with the invention amounts to a maximum of 5 volume percent at the start of the heat treatment in the reaction space, the residual oxygen in the reaction space is converted very fast in comparison with the methods known from the prior art in which the oxygen content at the start of the heat treatment amounts to approximately 21 volume percent by reaction of the residual oxygen with the zinc present in the reaction space and the substrate which usually contains high quantities of iron by the reactions starting at approximately 200° C. 3 Fe+2 O₂1 Fe₃O₄ und 2 Zn+O₂→2 ZnO so that the oxygen content is reduced to zero or to at least a few ppm a great deal faster than with the methods known from the prior art. Since no gas, no gas containing oxygen or gas which has been pretreated so that is has an oxygen content of a maximum of 100 ppm is added after the start of the heat treatment in the method in accordance with the invention, the oxygen content generated by the reactions shown above of 0 volume percent or of a few ppm is maintained over the total duration of the heat treatment. For this reason, very much less zinc is consumed by the reaction with the oxygen located in the reaction space in the method in accordance with the invention in comparison with the sherardizing processes known from the prior art and used in production scale so that the zinc consumption is less with respect to the surface of the substrate to be coated. In addition, also only a great deal less iron of the substrate is thereby converted to iron oxide by the reaction shown above so that the addition of filler can be dispensed with without a disturbing quantity of iron oxide being formed. For this reason, in the method in accordance with the invention, the addition of filler can be dispensed with, which results in a considerable reduction in the energy costs for the method in accordance with the invention in comparison with the methods known from the prior art using fillers.

The use of inert gases in zinc coating processes has admittedly already been described for laboratory engineering processes by Proskurin & Gorbunov, “Galvanizing, sherardizing and other zinc diffusion coatings”, Technicopy Limited, England, 1972, pages 45 to 48, by Pistofidis et al., “Microscopical study of zinc coatings”, G.I.T. Imaging & Microscopy, 2005, pages 48 to 50 and by Gorbunov et al., “Zinc diffusion coatings”, Zashchita Metallov, Vol. 1, No. 3, 1965, pages 314 to 318. In all these processes, however, the inert gas is continuously introduced into a side of the reaction space and is removed from the opposite side of the reaction space during the total heat treatment. Since the inert gas has a specific oxygen content by way of nature, a specific oxygen content is maintained in the reaction space during the total process duration. In addition, all these processes are carried out in the powder pack processes. No indication of a pretreatment of the inert gases resulting in an oxygen content of a maximum of 100 ppm is given in any of these documents.

The method in accordance with the invention is preferably carried out as a diffusion process or sherardizing process with the optional use of a filler.

Due to the reduced zinc requirement per surface of the substrate to be coated in the method in accordance with the invention, it is proposed in a further development of the idea of the invention to dimension the quantity of the coating agent, that is of the zinc, preferably in the form of zinc powder, such that the desired layer weight is reached plus a zinc excess which is determined, on the one hand, by the inner surface of the reaction space which is composed above all of the part surfaces of the substrate, of the alembic wall and of the installations and, on the other hand, by the residual oxygen content in the reaction space. The following empirically confirmed prescription for the quantity of the coating agent, that is of the zinc, derives from this: zinc quantity required to achieve the desired layer weight plus the excess zinc quantity of no more than 200 g per 1 m² inner surface of the reaction space plus a further zinc quantity of no more than 60 g per 1 volume percent residual oxygen and 1 m³ reaction space. The quantity of non-converted zinc which remains after the heat treatment in the reaction space and which has to be separated from the substrate and treated in a complex manner in order again to be used in the process can thus be minimized. Provided that a filler is used in the method in accordance with the invention, which is possible, but not preferred, the filling volume of the filler with respect to the (geometrical) volume of the reaction space amounts to less than 60%, particularly preferably less than 10% and very particularly preferably less than 1%. The quantities used in this embodiment are so small that the substrate or the substrates are not embedded or dipped fully into the zinc powder or into the mixture of zinc powder and filler in the heat treatment. This embodiment is thus, unlike the currently used sherardizing processes, not a powder pack process, but a dusting process. In powder pack processes, the substrate or substrates to be coated are by definition completely embedded, i.e. their total surface is embedded in the mixture of zinc powder and filler.

The method in accordance with the invention is generally suitable for the zinc coating of substrates which comprise a metal which can be alloyed with zinc, preferably iron and its alloys such as steel and cast iron, copper and its alloys and/or aluminum and its alloys. The method furthermore allows substrates to be coated in an almost unlimited variety with respect to shape and size.

In accordance with the invention, in the method for the coating of a surface of a least one substrate with zinc, the oxygen content in the atmosphere contained in the reaction space is set before the start of the heat treatment to less than or equal to 5 volume percent. To achieve a still low zinc consumption per substrate surface to be coated, the oxygen content in the atmosphere contained in the reaction space is preferably set before the start of the heat treatment to less than or equal to 1 volume percent, more preferably to less than or equal to 0.5 volume percent, particularly preferably to less than or equal to 0.1 volume percent, very particularly preferably to less than or equal to 0.05 volume percent and most preferably to less than or equal to 0.01 volume percent. The setting of the corresponding oxygen content before the start of the heat treatment can take place, for example, by purging the reaction space with a gas or gas mixture containing correspondingly little oxygen or no oxygen at all or by a single or plurality of evaluations of the reactor space and subsequent venting of the reactor space with a gas or gas mixture containing correspondingly little or no oxygen. The last-named variant can be carried out, for example, by two-time evacuation of the reaction space to a pressure of 20 mbar, with the reaction space being filled with inert gas between the individual evacuation steps.

As already presented, in the method in accordance with the invention, the oxygen content is reduced in the reaction space after the start of the heat treatment by reaction of the remaining residual oxygen with zinc and/or iron to trace quantities, for example to 0.1 ppm, after which no gas or gas containing at most very low quantities of oxygen is supplied to the reaction space. Particularly good results are in particular achieved when no gas at all or absolutely oxygen-free gas is supplied to the reaction space after the start of the heat treatment. However, it is also possible, albeit less preferred, to supply gas to the reaction space which has been pretreated such that it contains an oxygen content of a maximum of 100 ppm. It is preferred in this embodiment if the oxygen content of the gas amounts to a maximum of 10 ppm after the pretreatment, particularly preferably a maximum of 1 ppm and very particularly preferably a maximum of 0.1 ppm.

Tried and tested adsorption processes are suitable for the gas cleaning which are provided in industrial scale by the gas industry. Contaminants of hydrogen and oxygen can in this manner be reduced to less than 40 or 5 ppb.

Provided that gas is supplied to the reaction space during the heat treatment, this can be any gas which is inert with respect to zinc, that is does not react with zinc, such as one which is selected from the group which comprises noble gases, nitrogen, methane, C₁-C₄ alkanes, C₁-C₄ alkenes, C₁-C₄ alkines, silanes, hydrogen, ammonia and any desired combinations of two or more of the aforesaid compounds.

As already presented, a significant advantage of the method in accordance with the invention lies in the fact that no filler has to be used in it. In accordance with a preferred embodiment of the present invention, the filling volume of the filler preferably amounts with respect to the geometrical volume of the reaction space to less than 60%, preferably less than 10% filler, and particularly preferably less than 1%, with particularly preferably no filler at all being used. Fillers are here understood as heat-conductive compounds such as metal oxides such as alumina, magnesium oxide and the like, sand or the like.

It is proposed in a further development of the idea of the invention to use zinc powder as the coating agent in the method in accordance with the invention having a zinc content between 90 and 100% by weight and preferably having a zinc content between 99 and 100% by weight.

Zinc powder or zinc dust is preferably used having a mean grain size between 3 and 6 μm and a maximum particle size of 70 μm.

Generally, the coating agent can be supplied to the reaction space before or during the heat treatment. Provided that the coating agent is supplied to the reaction space before the heat treatment, it is preferred first to dust the substrate with the coating agent or to otherwise coat it outside the reaction space before the substrate thus dusted with coating agent is introduced into the reaction space and the heat treatment is started after reduction of the oxygen content in the reaction space to a maximum of 5 volume percent. An advantage of the other embodiment in which the coating agent is supplied to the reaction space during the heat treatment is the possibility of first, i.e. before the start of the heat treatment, introducing an auxiliary agent such as flux agent, which reacts with the coating agent, into the reaction space before the coating agent is introduced into the reaction space after the start of the heat treatment in order thus to prevent a reaction between this auxiliary agent and the coating agent before the start of the heat treatment.

Provided that a flux agent is preferably supplied to the reaction space before the heat treatment, it is preferably selected from the group which comprises aluminum chloride, zinc chloride, ammonium chloride, calcium chloride, chlorine, hydrogen chloride, hydrogen fluoride and any desired combinations of two or more of the aforesaid compounds.

Generally, the heat treatment can be carried out at any pressure, for example at a light overpressure, such as at a pressure in a range between 1 and 1.5 bar and preferably between 1.02 and 1.2 bar, or at an underpressure such as at a pressure in a range between 10-2 and 0.99 bar and preferably between 1 and 10 mbar. Whereas the advantage of working with an overpressure lies in the fact that no air can penetrate into the reaction space from the environment in the event of any leaks of the reaction space, when work is performed with underpressure an increase of the diffusion coefficient of the coating agent in the gas space is achieved. To avoid an introduction of oxygen via ambient air in the event of any leaks of the reaction space, it is preferred to carry out the heat treatment at an overpressure.

The method in accordance with the invention is also not particularly limited with respect to the temperature at which the heat treatment is carried out. Particularly good results are in particular obtained when the temperature for the heat treatment is set to a value in a range between 300 and 450° C. and particularly preferably between 340 and 400° C. The duration of the heat treatment primarily depends on the temperature set in the heat treatment and on the desired layer thickness of the zinc coating on the substrate. The heat treatment is preferably carried out for 0.1 to 24 hours and particularly preferably for 0.5 to 5 hours.

The at least one substrate to be coated with zinc is preferably cleaned outside the reaction space before the start of the heat treatment before it is introduced into the reaction space. The cleaning can take place by any process familiar to the skilled person for this purpose such as by mechanical surface treatment with a blasting medium, by stripping in alkaline or acid solutions as well as by treatment with a flux agent.

To achieve a particularly uniform coating of the at least one substrate with zinc, it is proposed in a further development of the idea of the invention to attach the at least one substrate to a rack outside the reaction space before the rack is introduced into the reaction space. The rack is preferably attached in a rotatable, tiltable, swingable, oscillatable or vibratable manner in the reaction space so that the rack is rotated, tilted, swung, oscillated or vibrated in the reaction space during the heat treatment.

In accordance with a further preferred embodiment of the present invention, the heat treatment is carried out such that the at least one substrate is also annealed during the heat treatment.

To ensure an ideal process management, it is proposed in a further development of the idea of the invention to measure and to control the pressure, the temperature and the oxygen content in the reaction space during the heat treatment.

It is furthermore preferred to distribute the coating agent in the reaction space by sputtering and circulating during the heat treatment. In this manner, a zinc coating can be obtained on the substrate with a particularly uniform layer thickness.

It is moreover preferred to remove the non-consumed coating agent and the calcine or the non-consumed coating agent from the reaction space after the heat treatment and to reuse the non-consumed part in a later process performance.

It can be advantageous in dependence on the later purpose of use of the coated substrate to passivate the coated substrate after the heat treatment. In this respect, all the passivation processes familiar to the skilled person can be used such as phosphate passivation, chrome passivation and carbonate passivation.

A further subject matter of the present invention is a method for the coating of a surface of at least one substrate with zinc, wherein the at least one substrate to be coated is heat treated together with zinc as the coating agent at a temperature between 200 and 500° C., wherein this method is carried out in an apparatus which includes a stationary furnace in whose interior a closable, stationary reaction space is provided wherein at least one rack is provided arranged in rotatable, tiltable, swingable, oscillatable or vibratable manner in the reaction space, said rack being designed such that at least one substrate can be fastened in it and wherein the oxygen content of the atmosphere contained in the reaction space is set to less than or equal to 5 volume percent before the start of the heat treatment.

This process management is preferred because a stationary furnace in whose interior a closable, stationary reaction space is provided is exceptionally sealable in contrast to the apparatus in which the known sherardizing processes are carried out in production scale, namely rotatable drum furnaces, and because a penetration of air surrounding the furnace into the reaction space can thus be reliably prevented on the carrying out of the heat treatment even if no overpressure is set in the reaction space during the heat treatment. For this reason, preferably all major seals in this apparatus are provided outside the reaction space.

A rotatable arrangement of the rack in the reaction space can be achieved, for example, in the reaction space via rollers or rolls arranged between the wall of the reaction space and the rack.

The apparatus moreover preferably has an injector which is configured such that zinc powder and/or a gas or a gas mixture can be introduced into the closed reaction space via it.

It is proposed in a further development of the invention to provide a pressure measuring device, a temperature measuring device and/or an oxygen measuring device in the reaction space in order thus to be able to measure and control the pressure, the temperature and/or the oxygen content in the carrying out of the method.

Furthermore, the apparatus can moreover have a cleaning which is configured such that the powder dust can be removed from the reaction space.

### BRIEF DESCRIPTION OF THE FIGURE

The present invention will be described in the following purely by way of example with reference to advantageous embodiments and to the enclosed drawing.

There is shown:

### DETAILED DESCRIPTION OF THE FIGURE

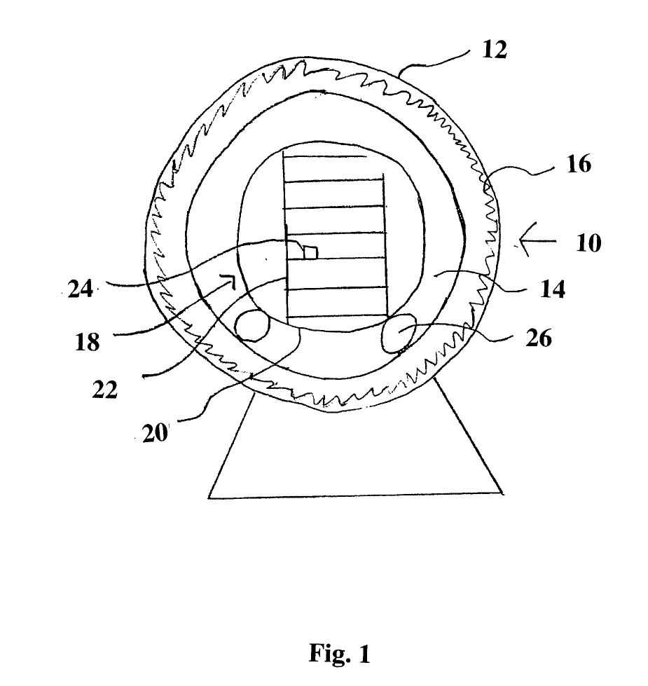

FIG. 1 a schematic view of an apparatus suitable for carrying out the method in accordance with the invention in accordance with an embodiment of the present invention.

The apparatus 10 shown in FIG. 1 comprises a substantially cylindrically designed stationary furnace 12 in whose interior a likewise substantially cylindrically designed, closable, stationary reaction space 14 is provided which is completely surrounded by walls at the circumferential side and at the rear side and at whose front side (not shown) a closable door is attached. A heating element 16 is provided between the wall of the reaction space 14 and the outer wall of the furnace 12 to heat the reaction space 14.

A rack 18 is arranged in the interior of the reaction space 14 which comprises a rack jacket 20 made as a hollow cylinder 20 open at its two end faces and a rack carrier 22 fastened to the rack jacket. A plurality of substrates 24, of which only one is shown in FIG. 1, are arranged and fastened in the rack carrier 22.

Two rollers 26 on which the rack 18 is rotatably supported are provided between the wall of the reaction space 14 at the peripheral side and the rack jacket 20. In addition, an injector (not shown) is provided at the door of the reaction space 14 via which coating agent can be introduced into the reaction space 14.

All the major seals (not shown) of the furnace 12 are arranged outside the reaction space 14 so that the furnace 12 can be closed in an airtight manner.

To carry out the method in accordance with an embodiment of the present invention, the substrates 24 to be coated are first cleaned thoroughly, preferably in blasting units, outside the furnace 12 and are subsequently fastened to the rack carrier 22 of the rack 18. The loaded rack 18 is thereupon introduced into the reaction space 14 through the door and is rotatably placed on the rollers 26 before the door is closed and the reaction space 14 is thus closed in a gastight manner.

The reaction space 14 is subsequently evacuated to a pressure of, for example, 150 mbar and it is subsequently filled with oxygen-free nitrogen. This procedure is repeated three times to lower the oxygen content in the atmosphere present in the reaction space 14 to a value of below 1 volume percent. On the last filling of the reaction space 14 with oxygen-free nitrogen, the pressure in the reaction space 14 is set to an overpressure of, for example, 1.3 bar.

The reaction space 14 is then heated via the heating element 16 to a temperature of 400° C. to start the heat treatment. During the heating time, coating agent in the form of zinc powder is introduced into the reaction space 14 via the injector, and indeed in a quantity which is dimensioned such that the desired layer weight is achieved plus a zinc excess which amounts to no more than 2 kg with respect to 1 m³ of the reaction space. During the heat treatment, the rack 18 is continuously rotated in the reaction space 14 via the rolls 26. In addition to this, the coating agent can be constantly circulated via a housing (not shown) arranged in the reaction space 14. The heat treatment is carried out for 2 hours, for example, after reaching the operating temperature of 400° C.

After the end of the heat treatment, the reaction space 14 is cooled and the remaining coating agent is removed from the surface of the substrates 24 with the help of a gas dedusting device before the rack 18 is removed from the reaction space 14 for the unloading of the substrates. Some of the coating agent can be reused in the following batch.

### Reference Numeral List

10 apparatus for zinc coating

12 stationary furnace

14 stationary reaction space

16 heating element

18 rack

20 rack jacket

22 rack carrier

24 substrate

26 rollers

We claim:

1. A method for the coating of a surface of at least one substrate with zinc, wherein the at least one substrate to be coated is heat treated together with zinc as a coating agent at a temperature between 200 and 500° C.,
wherein
before the start of the heat treatment in the reaction space in which the substrate to be coated is heat treated, setting the oxygen content in the atmosphere contained in the reaction space to less than or equal to 5 volume percent and starting the heat treatment in the atmosphere produced in this manner in the reaction space and carrying out the heat treatment in the reaction space, with no gas being supplied into the reaction space during the heat treatment or with no gas containing oxygen being supplied or with a gas being supplied which has been pretreated so that it contains an oxygen content of a maximum of 100 ppm.

2. A method in accordance with claim 1, wherein the quantity of the coating agent is dimensioned such that the desired layer weight is achieved plus a zinc excess of no more than 200 g per 1 m² of inner surface of the reaction space plus a further zinc quantity of no more than 60 g per 1 volume percent residual oxygen and 1 m³ reaction space.

3. A method in accordance with claim 1, wherein the method is carried out as a sherardizing method with optional use of a filler.

4. A method in accordance with claim 1, wherein the substrate is made of a metal which can be alloyed with zinc, preferably of iron and its alloys such as steel and cast iron, of copper and its alloys and/or of aluminum and its alloys.

5. A method in accordance with claim 1, wherein before the start of the heat treatment in the reaction space in which the substrate to be coated is heat treated, the oxygen content in the atmosphere contained in the reaction space is set to less than or equal to 1 volume percent, preferably to less than or equal to 0.5 volume percent, more preferably to less than or equal to 0.1 volume percent, particularly preferably to less than or equal to 0.05 volume percent and very particularly preferably to less than or equal to 0.01 volume percent.

6. A method in accordance with claim 1, wherein the gas is introduced into the reaction space during the heat treatment which has been pretreated so that it contains an oxygen content of a maximum of 10 ppm, preferably of a maximum of 1 ppm and particularly preferably of a maximum of 0.1 ppm.

7. A method in accordance with claim 1, wherein the gas introduced into the reaction space during the heat treatment which has been pretreated so that it contains an oxygen content of a maximum of 10 ppm is selected from the group comprising noble gases, nitrogen, methane, C₁-C₄ alkanes, C₁-C₄ alkenes, C₁-C₄ alkines, silanes, hydrogen, ammonia and any desired combinations of two or more of the aforesaid compounds.

8. A method in accordance with claim 1, wherein no filler is present in the reaction space during the heat treatment or, with respect to the volume of the reaction space, less than 60% of filler, preferably less than 10% of filler and particularly preferably less than 1% of filler is present.

9. A method in accordance with claim 1, wherein zinc powder having a zinc content between 90 and 100% by weight and preferably having a zinc content between 99 and 100% by weight is used as the coating agent.

10. A method in accordance with claim 1, wherein zinc powder or zinc dust having a mean grain size between 3 and 6 μm and a maximum particle size of 70 μm is used as the coating agent.

11. A method in accordance with claim 1, wherein the coating agent is supplied during the heat treatment.

12. A method in accordance with claim 1, wherein the substrate to be coated is dusted or coated with coating agent outside the reaction space before the start of the heat treatment.

13. A method in accordance with claim 1, wherein a flux agent is supplied to the reaction space before the heat treatment which is preferably selected from the group which comprises aluminum chloride, zinc chloride, ammonium chloride, calcium chloride, chlorine, hydrogen chloride, hydrogen fluoride and ay desired combinations of two or more of the aforesaid compounds.

14. A method in accordance with claim 1, wherein the heat treatment is carried out at a pressure between 1 and 1.5 bar and preferably between 1.02 and 1.2 bar.

15. A method in accordance with claim 1, wherein the heat treatment is carried out at a pressure between 10⁻² and 0.99 bar and preferably between 1 and 10 mbar.

16. A method in accordance with claim 1, wherein the heat treatment is carried out at a temperature between 300 and 450° C. and preferably between 340 and 400° C.

17. A method in accordance with claim 1, wherein the at least one substrate is cleaned before the start of the heat treatment outside the reaction space, preferably by mechanical surface treatment with a blasting agent, by stripping in alkaline or acid solutions and by treatment with a flux.

18. A method in accordance with claim 1, wherein the at least one substrate is attached to a rotatable rack outside the reaction space before the rack is introduced into the reaction space.

19. A method in accordance with claim 18, wherein the rack is rotated, tilted, swung, oscillated or vibrated during the heat treatment in the reaction space.

20. A method in accordance with claim 1, wherein the heat treatment is carried out such that the at least one substrate is also annealed during the heat treatment.

21. A method in accordance with claim 1, wherein the pressure, the temperature and the oxygen content are measured and controlled during the heat treatment in the reaction space.

22. A method in accordance with claim 1, wherein the coating agent is distributed in the reaction space by sputtering and circulating during the heat treatment.

23. A method in accordance with claim 1, wherein the non-consumed coating agent and the calcine or the consumed coating agent are removed from the reaction space after the heat treatment and the non-consumed portion is again supplied on a later method performance.

24. A method in accordance with claim 1, wherein the coated substrate is passivated after the heat treatment.

25. A method for the coating of a surface of at least one substrate with zinc, wherein the at least one substrate to be coated is heat treated together with zinc as a coating agent at a temperature between 200 and 500° C., wherein the method it is carried out in an apparatus (10) which comprises a stationary furnace (12) in whose interior a closable, stationary reaction space (14) is provided, with at least one rack (18) being provided arranged in a rotatable, tiltable, swingable, oscillatable or vibratable manner in the reaction space (14) and made such that at least one substrate (24) can be fastened in it; and in that the oxygen content of the atmosphere contained in the reaction space (14) is set to less than or equal to 5 volume percent before the start of the heat treatment.

26. A method in accordance with claim 25, wherein the apparatus (10) moreover has an injector which is configured such that zinc powder and/or a gas or a gas mixture can be introduced into the closed reaction space (14) via it.

27. A method in accordance with claim 25, wherein the apparatus (10) moreover has a cleaning which is configured such that the powder dust can be removed from the reaction space (14).
